(19) United States
(12) Patent Application Publication
(10) Pub. No.: US 2006/0246614 A1
(43) Pub. Date: Nov. 2, 2006

(54) Method for manufacturing gallium nitride-based semiconductor device

(75) Inventor: Hyo Won Suh, Soonchun (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/411,142

(22) Filed: Apr. 26, 2006

(30) Foreign Application Priority Data
Apr. 30, 2005 (KR) 10-2005-36571

(51) Int. Cl. H01L 21/00

(52) U.S. Cl. 438/22

(57) ABSTRACT

The invention provides a method for manufacturing a gallium nitride-based semiconductor device having low-density crystalline defects and high-quality crystalinity. In the manufacturing method according to the invention, first, a gallium oxide substrate is prepared. Then, a surface of the gallium oxide substrate is modified into a nitride via physical or chemical pretreatment to form a surface nitride layer having Ga—N bonding. Finally, gallium nitride-based semiconductor layer is formed on the surface nitride layer.

### RELATED APPLICATION

This application claims the benefit of Korean Patent Application No. 2005-36571 filed on Apr. 30, 2005 in the Korean Intellectual Property Office, the disclosure of which is incorporated herein by reference.

### BACKGROUND OF THE INVENTION

1. Field of the Invention

The present invention relates to a method for manufacturing a gallium nitride-based semiconductor. More particularly, the present invention relates to a method for manufacturing a gallium nitride-based semiconductor which ensures a GaN-based semiconductor layer with high-quality crystalinity. In the specification, a GaN-based semiconductor designates a binary, ternary or quaternary compound semiconductor having a composition expressed by AlₓGa_{y}In_{(1-X-y)}N, where 0≦x≦1, 0≦y≦1, and 0≦x+y≦1.

2. Description of the Related Art

Recently, a GaN-based semiconductor has garnered attention as a material that can be suitably applied to an opto electronic device of a short wavelength band, and a high-capacity electronic device. Especially, the GaN-based semiconductor has been spotlighted as a core material for blue and green light emitting diodes. To manufacture the GaN-based semiconductor light emitting device essentially requires a technique for growing a high-quality GaN-based single crystal. However, problematically, a substrate material for growing the GaN-based single crystal, which matches lattice constant and thermal expansion coefficient of the GaN-based single crystal, has not been commonly available.

Typically, the GaN-based single crystal is grown on a hetero-substrate such as a sapphire substrate via a vapor phase growth method such as Metal-Organic Chemical Vapor Deposition (MOCVD) and Hydride Vapor Phase Epitaxy (HVPE), or a Molecular Beam Epitaxy method (MBE). But due to big lattice mismatch between the hetero-substrate such as the sapphire substrate and the GaN single crystal (e.g., about 18% lattice mismatch between the sapphire substrate and GaN single crystal), the growth of the GaN-based semiconductor layer on the hetero-substrate leads to many defects such as dislocation.

In a conventional technique to reduce occurrence of defects by relieving such lattice mismatch, a variety of buffer layers such as a low temperature GaN buffer layer, a high temperature GaN buffer layer or an AlN buffer layer are formed on the sapphire substrate before growing the GaN-based semiconductor. For example, Appl. Phys. Lett 48, (1986), pp. 353 by Akasaki et al discloses a method for growing an AlGaN epitaxial layer on a low temperature AlN buffer layer formed on the sapphire substrate. Also, U.S. Pat. No. 5,290,393 teaches a method for growing an AlGaN epitaxial layer on the low-temperature GaN buffer layer formed on the sapphire substrate.

FIGS. 1a and 1b are schematic sectional views illustrating semiconductor structures 10 and 20 obtained according to a conventional manufacturing method of a GaN-based semiconductor.

First, referring to FIG. 1a, a low-temperature AlN buffer layer 13 and an AlGaN crystalline layer 15 are sequentially formed on a sapphire substrate 11. To obtain this semiconductor structure 10, first, an AlN polycrystalline layer is grown on the sapphire substrate 11 at a low temperature of 400 to 600° C. to form an AlN buffer layer 13. Thereafter, AlGaN is grown at a high temperature of about 1000° C. to form a desired AlGaN crystalline layer on the AlN buffer layer 13. Use of the AlN buffer layer 13 grown at a low temperature allows the AlGaN crystalline layer to have improved crystalinity.

Referring to FIG. 1b, a low-temperature GaN buffer layer 23 and an AlGaN crystal layer 25 are sequentially formed on a sapphire substrate 21. To produce such semiconductor structure 20, first, a low-temperature GaN polycrystal layer is grown on the sapphire substrate 21 at a temperature of about 600° C. to form the low-temperature GaN buffer layer 23. Then, with a temperature raised to about 1000° C., the polycrystal layer 23 is partially changed into a single crystal. The single crystal serves as a seed crystal to grow the AlGaN crystal layer 25 thereon later. Therefore, the crystalinity of the AlGaN crystal layer 25 can be improved relative to the AlGaN crystal layer 15 grown the AlN buffer layer l3.

However, despite use of the buffer layer, crystalline defects inevitably arise due to considerable lattice mismatch between the hetero-substrate such as the sapphire substrate and the GaN-based semiconductor. For example, even in case of using the low-temperature GaN buffer layer, it generates crystalline defects of about 10¹⁰/cm³, thereby hindering manufacture of a high-quality light emitting device such as Light Emitting Diodes (LEDs) or Laser Diodes (LDs). In addition, conventional methods are not appropriate for growing a bulk-type GaN-based semiconductor thick film having a thickness of more than tens of μm. As a result, there has been a demand for a technique for growing the GaN-based semiconductor crystalline layer having lower-density defects.

### SUMMARY OF THE INVENTION

The present invention has been made to solve the foregoing problems of the prior art and it is therefore an object of the present invention to provide a method for manufacturing a GaN-based semiconductor capable of inhibiting occurrence of crystalline defects and further improving crystalinity of the GaN-based semiconductor.

According to an aspect of the invention for realizing the object, there is provided a method for manufacturing a gallium nitride-based semiconductor device, comprising steps of:

preparing a gallium oxide substrate;

modifying a surface of the gallium oxide substrate into a nitride via physical or chemical pretreatment to form a surface nitride layer having Ga—N bonding; and

forming a gallium nitride-based semiconductor layer on the surface nitride layer.

According to the invention, a gallium oxide substrate such as a LiGaO₂ substrate or a Ga₂O₃ substrate is used instead of a sapphire substrate. Due to superior lattice match with GaN crystal, the gallium oxide can serve as a base structure for growing a GaN-based semiconductor layer having excellent crystalinity and low-density defects.

According to one embodiment of the invention, the physical or chemical pretreatment comprises irradiating an N₂⁺ ion beam to the surface of the gallium oxide substrate. Preferably, the ion beam is a reactive N₂⁺ ion beam having an energy of 0.001 keV to 10 MeV.

According to another embodiment of the invention, the physical or chemical pretreatment comprises nitrogen ion implanting (N+implanting) to the surface of the gallium oxide substrate. Preferably, the ion implanting is carried out at a dose of 1×10¹⁵/cm² to 1×10¹⁷/cm² and at an implantation energy of 10 keV to 10 MeV.

According to further another embodiment of the invention, the physical or chemical pretreatment comprises surface treatment to the surface of the gallium oxide substrate via nitrogen-containing plasma or radical. Preferably, the plasma or radial used for the surface treatment contains nitrogen and hydrogen.

The various physical or chemical pretreatment processes as described above allow the surface nitride layer having Ga—N bonding to be formed on the gallium oxide substrate. Such surface nitride layer serves as a useful seed layer to grow a GaN-based semiconductor layer thereon later, thus significantly enhancing crystalline quality of the GaN-based semiconductor layer.

According to a preferred embodiment of the invention, the manufacturing method further comprises cleaning the gallium oxide substrate before the step of forming the surface nitride layer. The cleaning comprises immersing the gallium oxide substrate in ethanol or water to apply ultrasonic wave.

According to further another embodiment of the invention, the manufacturing method further comprises forming a buffer layer on the surface nitride layer after the step of forming the surface nitride layer, the buffer layer having a composition expressed by AlₓGa₁₋ₓN, where 0≦x<1. For example, a buffer layer having a composition expressed by AlₓGa₁₋ₓN, where 0≦x<1 may be formed on the surface nitride layer at a low temperature of 300 to 900° C.

According to another preferred embodiment of the invention, the manufacturing method further comprises annealing the substrate having the surface nitride layer formed thereon or thermally cleaning the surface thereof after the step of forming the surface nitride layer. Preferably, the annealing is carried out at a temperature of 1000° C. to 1300° C. Also, the thermal cleaning of the surface is carried out at a temperature of 800° C. to 1200° C.

According to yet another embodiment of the invention, the manufacturing method further comprises separating or removing the gallium oxide substrate after the step of forming the GaN semiconductor layer. For example, to obtain a GaN-based substrate, the GaN-based semiconductor layer is formed to thickness of 30 μm or more and then the gallium oxide substrate is separated or removed.

### BRIEF DESCRIPTION OF THE DRAWINGS

The above and other objects, features and other advantages of the present invention will be more clearly understood from the following detailed description taken in conjunction with the accompanying drawings, in which:

FIG. 1a is a sectional view illustrating a semiconductor structure manufactured according to a method for manufacturing a gallium nitride-based semiconductor according to the prior art;

FIG. 1b is a sectional view illustrating a semiconductor structure manufactured according to another method for manufacturing the gallium nitride-based semiconductor according to the prior art;

FIG. 2 is a schematic flow chart illustrating a method for manufacturing a gallium nitride-based semiconductor according to the invention;

FIGS. 3a to 3d are sectional views for explaining a method for manufacturing the gallium-nitirde semiconductor according to one embodiment of the invention; and

FIGS. 4a to 4c are sectional views for explaining a method for manufacturing the gallium nitride-based semiconductor according to another embodiment of the invention.

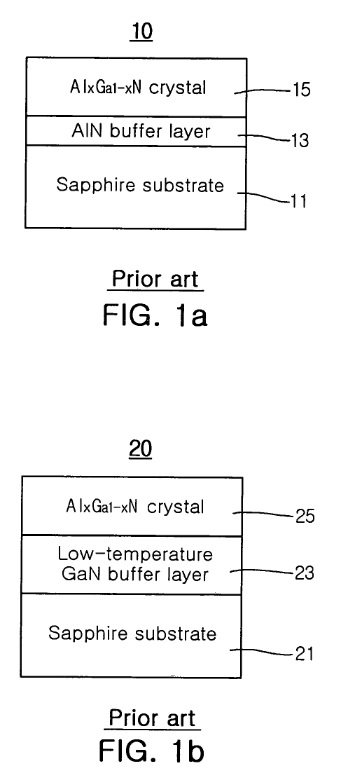

### DETAILED DESCRIPTION OF THE PREFERRED EMBODIMENT

The present invention now will be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference signs are used to designate the same or similar components throughout.

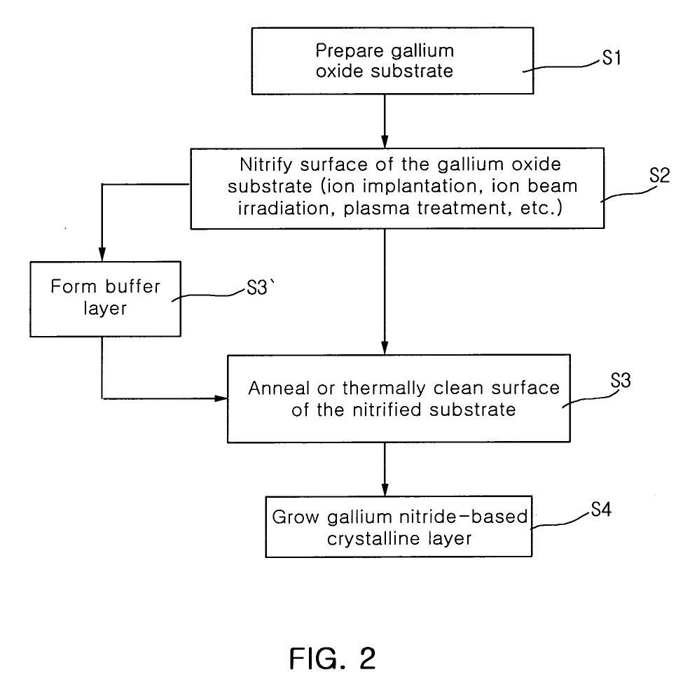

FIG. 2 is a schematic flow chart illustrating a method for manufacturing a GaN-based semiconductor according to the invention. Referring to FIG. 2, first, a gallium oxide substrate such as a LiGaO₂ substrate or a Ga₂O₃ substrate is prepared in S1. The gallium oxide substrate exhibits much higher lattice match with a GaN crystal than a conventional sapphire substrate. For example, the LiGaO₂ crystal has a crystalline structure and lattice constant considerably similar to those of the GaN crystal, with only 0.1 to 4% of lattice mismatch therebetween.

In greater detail, the LiGaO₂ crystal has lattice constants a, b and c expressed by a=5.402 Å, b=6.372 Å, and c=5.007 Å. The LiGaO₂ crystal is structured such that Zn atoms are substituted by Li and Ga atoms in a ZnO crystal having a wurtzite structure. The LiGaO₂ crystal can be easily grown by the general Czochralski method. Especially, lattice mismatch between the LiGaO₂ crystal and GaN crystal is merely about 0.8% on a basal plane (0001) (an average lattice mismatch therebetween is 0.9% at a room temperature). Other gallium oxide crystals such as Ga₂O₃ crystal exhibit excellent lattice match with the GaN crystal. Therefore, in case of growing the GaN crystalline layer on the gallium oxide substrate, low-density defects are attainable.

However, in order to grow the GaN-based semiconductor layer having lower density defects and superior crystalinity, a surface of the gallium oxide substrate needs to be reformed or modified before growing the GaN-based semiconductor. That is, as shown in FIG. 2, the surface of the gallium oxide layer is nitrified via physical or chemical surface treatment such as ion implantation, ion beam irradiation, plasma or radical treatment in S2. Such nitrification treatment allows a surface nitride layer having Ga—N bonding to be formed on the gallium oxide layer. The surface nitride layer serves as a high-quality seed layer to grow the GaN semiconductor crystal thereon later. Preferably, the gallium oxide substrate is cleaned before nitrifying the gallium oxide substrate.

Thereafter, the nitrified substrate is annealed or its surface is thermally cleaned in S3. In case of minor damage to lattice, the annealing or the thermal cleaning of the surface may not be conducted. Optionally, between the substrate nitrifying step and annealing step (or surface thermal cleaning), a buffer layer such as a low-temperature AlₓGa₁₋ₓN buffer layer may be formed on the surface nitride layer in S3′.

Next, a desired GaN-based semiconductor layer is grown on the surface nitride layer in S4. The GaN-based semiconductor layer exhibits very low-density defects and superior crystalinity owing to the gallium oxide substrate having excellent lattice match with GaN and the surface nitride layer providing a high-quality seed layer as an underlying structure.

Thereafter, to produce a desired device (e.g, LED), GaN-based epitaxial layers having various compositions and thickness may be grown further. Also, to manufacture a GaN substrate, after growing the GaN-based semiconductor layer to great thickness of 30 μm or more in S4, the gallium oxide substrate may be separated or removed from the GaN-based semiconductor layer.

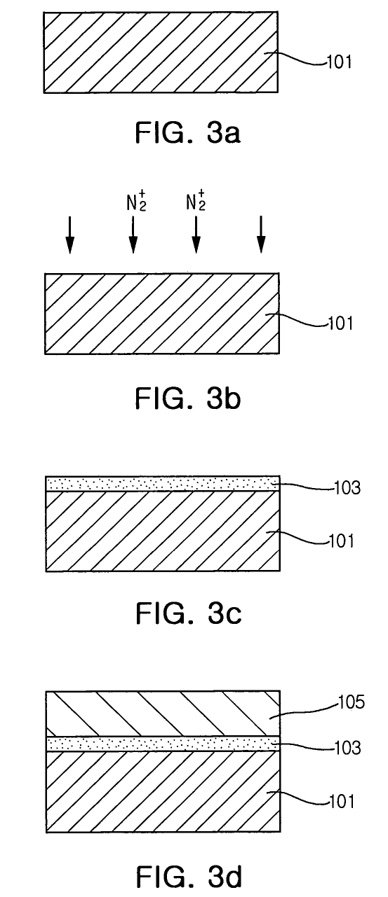

FIGS. 3a to 3d are sectional views for explaining a method for manufacturing a GaN-based semiconductor according to one embodiment of the invention. First, referring to FIG. 3a, a gallium oxide substrate 101 made of a Ga₂O₃ crystal or a LiGaO₂ crystal is prepared. Then, the gallium oxide substrate 101 is immersed in ethanol or water, and applied with ultrasonic wave to be cleaned.

Then, as shown in FIG. 3b, a reactive N₂⁺ ion beam is irradiated onto the gallium oxide substrate 101 at a predetermined amount, modifying the surface of the gallium oxide substrate 101 into a nitride. Preferably, when the ion beam irradiation is carried out, the reactive N₂⁺ ion beam has an energy of 0.001 keV to 10 MeV. The ion beam irradiated nitrifies the surface of the gallium oxide substrate 101, thereby forming a surface nitride layer 103 on the substrate 101 (see FIG. 3c).

In a detailed explanation, a nitrogen gas or nitrogen-containing gas such as N₂, N₂ and H₂, or NH₃ is used as a reactive source gas to form an N₂⁺ ion beam in a reactive chamber where a gallium oxide substrate 101 is placed. Then, through irradiation of a reactive N₂⁺ ion beam to the gallium oxide substrate 101, the bonding between oxygen and other atom can be broken near the surface of the substrate 101. With nitrogen atoms from the ion beam taking places of oxygen atoms, at least some oxygen atoms are substituted by nitrogen atoms. This allows formation of a nitride layer 103 having Ga—N bonding on the substrate. In fact, oxygen atoms are easily substitutable with nitrogen atoms, due to a similar ion radius by the density functional theory. That is, based on a calculation of a theoretical ion radius by the density functional theory, the inter-ion distance (1.88 Å) of nitrogen is very similar to the inter-ion distance (1.93 Å) of oxygen. Therefore, oxygen atoms near the surface of the substrate 101 are easily substituted with nitrogen atoms by the reactive N₂⁺ ion beam irradiated. The surface nitride layer 103 serves as a high-quality seed layer to grow GaN-based semiconductor layer thereon later. Moreover, the surface nitride layer 103 serves as a barrier layer which prevents heterogeneous atoms such as Li present in the substrate 101 (e.g., in case of using a LiGaO₂ substrate) from diffusing to the GaN-based semiconductor layer.

Then, preferably, the nitrified substrate is annealed or its surface is thermally cleaned. The annealing may be performed at a temperature of 1000° C. to 1300° C. The thermal cleaning of the surface may be carried out at a temperature of 800° C. to 1200° C. in such a cleaning or etching gas atmosphere as HCl or ammonia gas. Such annealing or surface thermal cleaning restores and removes lattice damage on the surface nitride layer possibly caused by ion beam irradiation. In case of minor damage to lattice, the annealing or surface thermal cleaning may not be conducted.

Thereafter, as shown in FIG. 3d, a GaN-based crystal is grown on the surface nitride layer 103 to obtain a GaN-based semiconductor layer 105 having low-density defects and excellent crystalinity. The GaN-based semiconductor layer 105 may be grown, for example, by MOCVD or MBE. Since the surface nitride layer 103 is originated from a Ga₂O₃ crystal or a LiGaO₂ crystal (gallium oxide substrate 101), it exhibits superior lattice match with a GaN crystal. In addition, the surface nitride layer 103 forms an oxygen-deficient (low oxygen density) film due to substitution by nitrogen atoms. In general, excess oxygen atoms induce defects in growth of the GaN crystal layer, adversely affecting the GaN crystal layer as a whole. Therefore, the surface nitride layer 103 with superior lattice match and oxygen deficiency allows easy growth of the high-quality GaN semiconductor layer 105 having low-density crystalline defects thereon.

In the aforesaid embodiment, the reactive N₂⁺ ion beam was irradiated onto the substrate 101, modifying its surface into a nitride, but other physical or chemical surface treatment may be employed. For example, a surface of the gallium oxide substrate 101 may be modified into the nitride by implanting nitrogen ions (N⁺). Preferably, the nitrogen ions are implanted into the gallium oxide substrate 101 at a dose of 1×10¹⁵/cm² to 1×10¹⁷/cm² and at an implantation energy of 10 keV to 10 MeV to form a surface nitride layer on the gallium oxide substrate 101.

In an alternative method to modifying a surface of the gallium oxide substrate into the nitride, the surface of the gallium oxide substrate 101 may be treated via nitrogen-containing plasma or radical. Preferably, in order to make nitrogen atoms more soluble in the surface of the substrate 101, nitrogen and hydrogen-containing plasma or radical is utilized to treat the surface of the substrate 101.

The aforesaid method for manufacturing the GaN-based semiconductor can be easily applied not only to a GaN-based LED device but also to a GaN-based thick film or GaN-based substrate having thickness of more than tens of μm. For example, in order to obtain the GaN-based substrate, the gallium oxide substrate 101 may be separated or removed after forming the GaN-based semiconductor layer 105 to a thickness of 30 μm or more. In this case, the gallium oxide substrate 101 is separated from the GaN-based semiconductor layer 105 or removed, for example, by laser irradiation, wet-etching or chemical mechanical polishing.

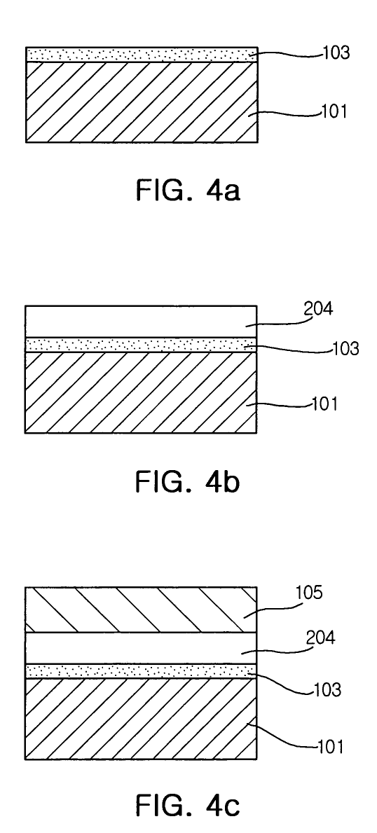

FIGS. 4a to 4c are sectional views for explaining a method for manufacturing a GaN-based semiconductor according to another embodiment of the invention. First, as shown in FIGS. 3a and 3b, a reactive N₂⁺ ion beam is irradiated onto a cleaned gallium oxide substrate 101, modifying its surface into a nitride. As described above, instead of the reactive N₂⁺ ion beam irradiation, nitrogen ion implantation, plasma or radical treatment may be employed. Consequently, as shown in FIG. 4a, a surface nitride layer 103 having Ga—N bonding is formed on the gallium oxide substrate 101.

Next, as shown in FIG. 4b, a high-temperature or low-temperature AlₓGa₁₋ₓN buffer layer 204 is formed on the surface nitride layer 103. For example, the AlₓGa₁₋ₓN buffer layer, where 0≦x<1 can be deposited on the surface nitride layer 103 at a low temperature of 300° C. to 900° C. Such buffer layer 204 significantly lowers defect density of the GaN-based crystal layer which will be grown later. Thereafter, preferably, the surface nitride layer 103 is annealed or its surface is thermally cleaned to restore or eliminate lattice damage possibly caused by ion beam irradiation.

Then, as shown in FIG. 4c, the GaN-based crystal is grown by CVD such as MOCVD or PVD such as MBE to form a GaN-based semiconductor layer 105 on the buffer layer 204. Since the GaN-based crystal is grown over the surface nitride layer 103 and buffer layer 204 acting as a foundation layer, the GaN-based semiconductor layer 105 has low-density defects and high-quality crystalinity. In the embodiment of the invention, the gallium oxide substrate 101 can be separated or removed to produce the GaN-based substrate.

According to the invention as stated above, a GaN-based semiconductor layer is formed on a surface nitride layer obtained by reforming a surface of a gallium oxide substrate into a nitride, thereby restraining occurrence of defects further and improving crystalinity of the GaN-semiconductor more. Consequently, the invention allows manufacture of a light emitting device such as LED improved in electrical optical properties and ensures a high-quality GaN-based substrate through separation or removal of the gallium oxide substrate.

While the present invention has been shown and described in connection with the preferred embodiments, it will be apparent to those skilled in the art that modifications and variations can be made without departing from the spirit and scope of the invention as defined by the appended claims.

What is claimed is:

1. A method for manufacturing a gallium nitride-based semiconductor device, comprising steps of:
preparing a gallium oxide substrate;
modifying a surface of the gallium oxide substrate into a nitride via physical or chemical pretreatment to form a surface nitride layer having Ga—N bonding; and
forming a gallium nitride-based semiconductor layer on the surface nitride layer.

2. The method according to claim 1, wherein the gallium oxide substrate comprises a LiGaO₂ substrate or a Ga₂O₃ substrate.

3. The method according to claim 1, wherein the physical or chemical pretreatment comprises irradiating an N₂⁺ ion beam to the surface of the gallium oxide substrate.

4. The method according to claim 3, wherein the ion beam is a reactive N₂⁺ ion beam having an energy of 0.001 keV to 10 MeV.

5. The method according to claim 1, wherein the physical or chemical pretreatment comprises nitrogen ion implanting to the surface of the gallium oxide substrate.

6. The method according to claim 5, wherein the ion implanting is carried out at a dose of 1×10¹⁵/cm² to 1×10¹⁷/cm² and at an implantation energy of 10 keV to 10 MeV.

7. The method according to claim 1, wherein the physical or chemical pretreatment comprises surface treatment to the surface of the gallium oxide substrate via nitrogen-containing plasma or radical.

8. The method according to claim 7, wherein the plasma or radial used for the surface treatment contains nitrogen and hydrogen.

9. The method according to claim 1, further comprising cleaning the gallium oxide substrate before the step of forming the surface nitride layer.

10. The method according to claim 1, further comprising forming a buffer layer on the surface nitride layer after the step of forming the surface nitride layer, the buffer layer having a composition expressed by AlₓGa₁₋ₓN, where 0≦x<1.

11. The method according to claim 1, further comprising annealing the substrate having the surface nitride layer formed thereon or thermally cleaning the surface thereof after the step of forming the surface nitride layer.

12. The method according to claim 11, wherein the annealing is carried out at a temperature of 1000° C. to 1300° C.

13. The method according to claim 11, wherein the thermal cleaning of the surface is carried out at a temperature of 800° C. to 1200° C.

14, The method according to claim 1, further comprising separating or removing the gallium oxide substrate after the step of forming the GaN semiconductor layer.
